(19) United States
(12) Patent Application Publication
(10) Pub. No.: US 2026/0129780 A1
(43) Pub. Date: May 7, 2026

(54) HEAT REUSE PROXIMATE RACK PANELS

(71) Applicant: Vertiv Corporation, Westerville, OH (US)

(72) Inventors: Matthew Griffith Keller, Westerville, OH (US); Sarah Kimberly Kolomiiets, Westerville, OH (US)

(21) Appl. No.: 19/376,577

(22) Filed: Oct. 31, 2025

Related U.S. Application Data
(60) Provisional application No. 63/715,224, filed on Nov. 1, 2024.

(51) Int. Cl. H05K 7/14; H10N 10/17

(52) U.S. Cl. CPC H05K 7/1438; H10N 10/17

(57) ABSTRACT

An information technology (“IT”) system includes a system housing, an IT stack, and a thermoelectric generation system. The IT stack can be capable of generating heat during operation thereof, the IT stack located within the system housing. The thermoelectric generation system can be mounted above the IT stack and within the system housing. The thermoelectric generation system can be configured to convert heat generated by the IT stack to an amount of electrical energy.

### CROSS REFERENCE TO RELATED PATENT APPLICATIONS

This application claims the benefit of U.S. Provisional Patent Application No. 63/715,224, filed November 1, 2024, and entitled “HEAT REUSE PROXIMATE RACK PANELS,” which is incorporated herein by reference in its entirety.

### BACKGROUND

Heat generated in information technology (“IT”) racks must be removed to keep the related IT equipment functioning. Heat is generally removed via a Cold Air Handler (“CRAC” and “CRAH”) and fans. With the adoption of direct-to-chip cooling and rear door heat exchange units, heat can collect at the top of the racks, despite removal efforts. Up to 25% of the heat can still be expected to be air-cooled even with direct to chip cooling, due to current designs. That is, the air proximate the IT equipment, particularly above the equipment racks, can still be expected to be warmer than desired, requiring removal thereof.

### SUMMARY

In an embodiment of the present disclosure, an information technology (“IT”) system includes a system housing, an IT stack, and a thermoelectric generation system. The IT stack can be capable of generating heat during operation thereof, the IT stack located within the system housing. The thermoelectric generation system can be mounted above the IT stack and within the system housing. The thermoelectric generation system can be configured to convert heat generated by the IT stack to an amount of electrical energy.

In an embodiment, the IT system can include a series of thermoelectric generator pads, a respective pad mounting component corresponding to each separate thermoelectric generator pad, and a contained phase change carrying material, each thermoelectric generator pad attached to the phase change carrying material via a corresponding respective pad mounting component.

In an embodiment, the thermoelectric generator pads are in electrical connection in sequence.

In an embodiment, the thermoelectric generator pads are oriented toward the IT stack.

### BRIEF DESCRIPTION OF THE DRAWINGS

The Detailed Description is described with reference to the accompanying figures.

FIG. 1 is a schematic diagram of an information technology (“IT”) system in profile, in accordance with an example embodiment of the present disclosure.

FIG. 2 is a schematic diagram of a thermoelectric generation system of an IT system, as shown in FIG. 1, in profile.

FIG. 3 is an overhead cross-section schematic diagram of a thermoelectric generation system, as shown in FIGS. 1 and 2.

### DETAILED DESCRIPTION

Aspects of the disclosure are described more fully hereinafter with reference to the accompanying drawings, which form a part hereof, and which show, by way of illustration, example features. The features can, however, be embodied in many different forms and should not be construed as limited to the combinations set forth herein; rather, these combinations are provided so that this disclosure will be thorough and complete, and will fully convey the scope. The following detailed description is, therefore, not to be taken in a limiting sense.

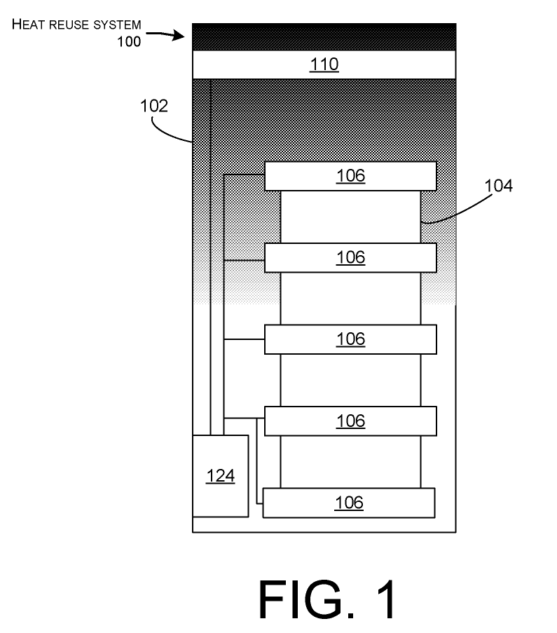

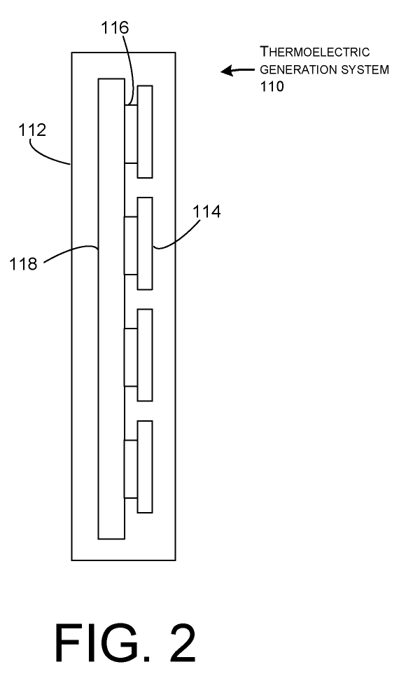

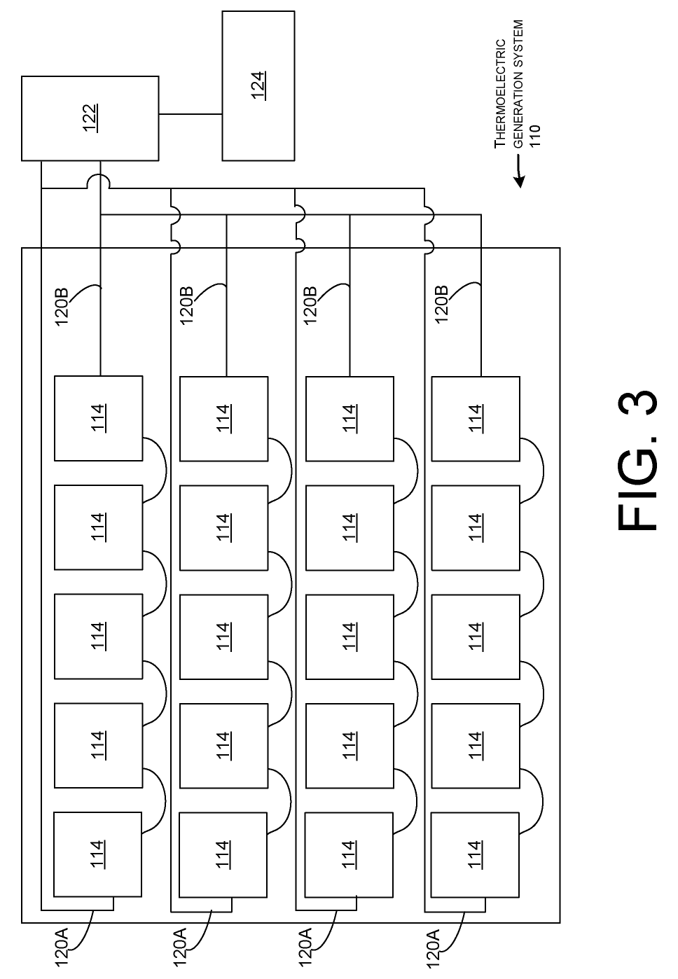

According to example embodiments of the present disclosure, byproduct thermal energy is converted to electrical energy to achieve cooling of a region above equipment racks. As can be seen from FIGS. 1-3, thermoelectric generators positioned above the IT equipment (e.g., above an equipment rack) can supply power to the IT equipment by harvesting waste heat at the top of the equipment rack. This offset cannot provide all the power needed to drive operation of the proximal IT equipment, but the recovered energy may provide enough harvested DC power to power additional devices and/or offset utility power into a DC power shelf or another device. It is to be understood that any locations housing IT equipment in equipment racks or even modular configurations (e.g., an arrangement promoting heat to rise and collect above the IT equipment) may benefit from the proposed thermoelectric generation system. That is, the present thermoelectric generation system can be employed, for example, in data centers, modular deployments, edge applications, telecommunications (e.g., OSP (Outside Plant)) cabinets, battery cabinets, or other IT-related sites dealing with heat accumulation there-above and which may otherwise benefit from the power conversion of that excess heat.

The present thermoelectric generation system can provide benefits to customers offsetting their power draws. The present system also can be a new tool within the sustainable usage, utilizing waste heat that may not be recognized or utilized. Further, there can be a cost reduction associated with heat reuse that is converted to electrical energy.

According to a present embodiment, the thermoelectric generation system can include multiple chained thermoelectric solid-state generators mounted as part of an equipment rack top-side panel, as a distinct unit on top of a rack panel, as a retrofit panel, or as a purpose-built rack panel, in each instance positioned above a grouping of power-consuming IT equipment. These thermoelectric solid-state generators can be mounted via thermal paste onto a contained phase change material, normally solid at specific temperatures, to provide a cold side to the thermoelectric generators. The hot side of the thermoelectric generators can be placed (e.g., oriented) towards the interior of the equipment rack to be exposed to waste heat (e.g., a heat collection zone above the IT equipment). The generators can be in electrical connection in sequence to a monitorable voltage regulator, and a power supply from which IT equipment draws power. Once active, this power supply can provide a selectable amount of DC voltage for additional devices and/or be directable (e.g., via hard wiring) into a DC power shelf.

This present thermoelectric system allows reuse directly at the equipment rack level (e.g., proximal the power-consuming equipment generating the most heat) while the equipment rack (e.g., IT equipment carried thereby) is at use.

FIGS. 1-3 illustrate a heat reuse system 100, in accordance with an example embodiment of the present disclosure. The heat reuse system 100 can generally include a system housing 102, an IT stack 104, and a thermoelectric generation system 110. The IT stack 104 can be in the form of an equipment rack in combination with any of various power-consuming IT equipment carried by the equipment rack (the individual elements of the IT stack 104 not illustrated). The IT equipment may include, by way of example, servers, batteries, rectifiers, and/or system management equipment. The IT stack 104 further includes one or more power shelves 106, and individual items of IT equipment are in electrical connection with one or more power shelves 106. A system housing 102 can further includes one or more power supplies, from which power shelves 106 can draw power through one or more power cable connections. By way of example without limitation thereto, high-voltage current carried by busbars can be rectified and stepped down to supply power to one or more power supplies.

The thermoelectric generation system 110 can include a mounting unit 112, a series of thermoelectric generator pads 114, a respective pad mounting component 116 corresponding to each thermoelectric generator pad 114, and a phase change carrying material 118. The thermoelectric generation system 110 can further include a positive electrical interconnection 120A, a negative electrical interconnection 120B, a direct current (“DC”) voltage regulator 122, and a power supply 124 having a DC voltage output.

One or more IT stacks 104 can be positioned, housed, and/or mounted within the system housing 102, and the one or more IT stacks 104 can be associated with any of data centers, modular deployments, edge applications, telecommunications (e.g., OSP (Outside Plant)) cabinets, battery cabinets, or other IT-related sites. By way of example, a system housing 102 can be a telecommunications cabinet, a battery cabinet, and other such enclosure housing an equipment rack. A given IT stack 104, as alluded to above, of the heat reuse system 100 can include components consuming power ranging from tens to hundreds of kilowatts, yielding temperatures in excess of 80 or over 100 degrees Fahrenheit without cooling, and, even with current IT cooling systems and the advent of liquid cooling, a certain amount of heat can tend to collect at the top of the equipment racks (e.g., above an equipment rack structure associated with a corresponding IT stack 104), despite heat removal efforts. For example, temperatures at the top of an IT stack 104 enclosed in a system housing 102 can be 20% higher than temperatures at the bottom, approximately illustrated by the degrees of darkened shading in FIG. 1. A respective thermoelectric generation system 110 can be mounted above and on a corresponding IT stack 104 via the mounting unit 112 of the respective thermoelectric generation system 110. In an embodiment, a given thermoelectric generation system 110 can be retrofit mounted atop an IT stack 104 or purpose-built atop an IT stack 104 (e.g., proximate the top of an equipment rack of the IT stack 104, with either a retrofit or purpose-built situation). Each thermoelectric generation system 110 can be configured to convert thermal energy to electrical energy.

In an embodiment, a thermoelectric generator (also called a Seebeck generator) is a solid-state device that converts heat (driven by temperature differences) directly into electrical energy through a phenomenon called the Seebeck effect (a form of thermoelectric effect). Thermoelectric generators can have a conversion efficiency of about 5-8%. In some embodiments, a thermoelectric generator may use a highly doped semiconductor made from bismuth telluride (Bi₂Te₃), lead telluride (PbTe), calcium manganese oxide (Ca₂Mn₃O₈), or combinations thereof. In the present embodiment, each thermoelectric generator pad 114 can be such a thermoelectric generator, with each thermoelectric generator pad 114 being oriented toward a heat source. In the present case, each thermoelectric generator pad 114 can be oriented toward (i.e., face) a corresponding IT stack 104 to capture an amount of the heat (e.g., waste heat) rising therefrom.

A series of thermoelectric generator pads 114, a respective pad mounting component 116 corresponding to each separate thermoelectric generator pad 114, and a contained phase change carrying material 118 can together be carried via the corresponding mounting unit 112 of the thermoelectric generation system 110. Each thermoelectric generator pad 114 can be attached to the phase change carrying material 118 via a corresponding respective pad mounting component 116. Each pad mounting component 116 can be in the form of a thermal paste or a thermal adhesive, each pad mounting component 116 serving as a thermal interface material with the phase change carrying material 118. Such phase change materials are commonly referred to as PCMs. In some embodiments, the PCM can be, by way of example only, salt hydrates, fatty acids and/or esters, and/or various paraffins (such as octadecane). (It is to be understood, however, that the phase change carrying material can be any suitable PCM for the operating temperatures in play.) The thermoelectric generator pads 114 (as the thermoelectric solid-state generators) can be mounted via thermal paste (i.e., a corresponding pad mounting component 116) onto a contained phase change carrying material 118, normally solid at specific temperatures, to provide the cold side to the thermoelectric generators. The hot side of the thermoelectric generators (i.e., thermoelectric generator pads 114) can be placed towards (i.e., facing) the interior of the equipment rack (i.e., towards the IT stack 104) to be exposed to waste heat rising therefrom. The thermoelectric generator pads 114 generate power from a temperature differential between the hold side and the hot side, according to the Seebeck effect as described above.

The generators (i.e., the thermoelectric generator pads 114) can be in electrical connection in sequence, via the positive electrical interconnection 120A and a negative electrical interconnection 120B, to a monitorable voltage regulator 122 and to a power supply 124 having a DC voltage output. Power shelves 106 can draw power from the DC voltage output by power cable connections to the power supply 124.

According to some embodiments, the power supply 124 is supplemental to one or more primary power supplies and supplies lower wattage than the one or more primary power supplies. According to some embodiments, the one or more primary power supplies can draw power from current carried by busbars. According to some embodiments, the one or more primary power supplies can be integral to the system housing 102.

According to some embodiments, the power supply 124 has switchable electrical inputs, including a first electrical input drawing power from current carried by busbars, and a second electrical input drawing power from thermoelectric generator pads 104.

In an embodiment, the positive electrical interconnection 120A and a negative electrical interconnection 120B together may define a series circuit. Once active, this thermoelectric generation system 110 can provide a selectable amount of DC voltage in the form of the power supply 124 having a DC voltage output for powering additional devices or for being directed into a DC power shelf (not shown).

The heat reuse system 100 can further include at least one processor for controlling the operation of the various components of the heat reuse system 100 (e.g., the one or more IT stacks 104, and/or the one or more thermoelectric generation systems 110). The at least one processor may be implemented as any suitable processor(s), such as at least one general purpose processor, at least one central processing unit (“CPU”), at least one image processor, at least one graphics processing unit (“GPU”), at least one field-programmable gate array (“FPGA”), and/or at least one special purpose processor configured to execute instructions for performing (e.g., collectively performing if more than one processor) any or all of the operations disclosed throughout.

In one embodiment, several portions of the subject matter described herein may be implemented via Application Specific Integrated Circuits (“ASICs”), FPGAs, digital signal processors (“DSPs”), or other integrated formats. However, those skilled in the art will recognize that some aspects of the embodiments disclosed herein, in whole or in part, can be equivalently implemented in integrated circuits, as one or more computer programs running on one or more computers (e.g., as one or more programs running on one or more computer systems), as one or more programs running on one or more processors (e.g., as one or more programs running on one or more microprocessors), as firmware, or as virtually any combination thereof, and that designing the circuitry and/or writing the code for the software and/or firmware would be well within the skill of one of skill in the art in light of this disclosure. In addition, those skilled in the art will appreciate that the mechanisms of the subject matter described herein are capable of being distributed as a program product in a variety of forms, and that an illustrative embodiment of the subject matter described herein applies regardless of the particular type of signal bearing medium used to actually carry out the distribution. Examples of a signal bearing medium include, but are not limited to, the following: a recordable type medium such as a floppy disk, a hard disk drive, a Compact Disc (“CD”), a Digital Video Disk (“DVD”), a digital tape, a computer memory, etc.; and a transmission type medium such as a digital and/or an analog communication medium (e.g., a fiber optic cable, a waveguide, a wired communications link, a wireless communication link, etc.).

In a general sense, those skilled in the art will recognize that the various aspects described herein which can be implemented, individually and/or collectively, by a wide range of hardware, software, firmware, or any combination thereof can be viewed as being composed of various types of “electrical circuitry.” Consequently, as used herein “electrical circuitry” includes, but is not limited to, electrical circuitry having at least one discrete electrical circuit, electrical circuitry having at least one integrated circuit, electrical circuitry having at least one application-specific integrated circuit, electrical circuitry forming a general purpose computing device configured by a computer program (e.g., a general purpose computer configured by a computer program which at least partially carries out processes and/or devices described herein, or a microprocessor configured by a computer program which at least partially carries out processes and/or devices described herein), electrical circuitry forming a memory device (e.g., forms of random access memory), and/or electrical circuitry forming a communications device (e.g., a modem, communications switch, or optical-electrical equipment). Those having skill in the art will recognize that the subject matter described herein may be implemented in an analog or digital fashion or some combination thereof.

Those having skill in the art will recognize that it is common within the art to describe devices and/or processes in the fashion set forth herein, and thereafter use engineering practices to integrate such described devices and/or processes into data processing systems. That is, at least a portion of the devices and/or processes described herein can be integrated into a data processing system via a reasonable amount of experimentation. Those having skill in the art will recognize that a typical data processing system generally includes one or more of a system unit housing, a video display device, a memory such as volatile and non-volatile memory, processors such as microprocessors and digital signal processors, computational entities such as operating systems, drivers, graphical user interfaces, and applications programs, one or more interaction devices, such as a touch pad or screen, and/or control systems including feedback loops and control motors (e.g., feedback for sensing position and/or velocity; control motors for moving and/or adjusting components and/or quantities). A typical data processing system may be implemented utilizing any suitable commercially available components, such as those typically found in data computing/communication and/or network computing/communication systems.

As used throughout and as would be appreciated by those skilled in the art, “at least one non-transitory computer-readable medium” or “memory” may refer to as at least one non-transitory computer-readable medium (e.g., at least one computer-readable medium implemented as hardware); at least one non-transitory processor-readable medium, at least one memory (e.g., at least one nonvolatile memory, at least one volatile memory, or a combination thereof); e.g., at least one random-access memory, at least one flash memory, at least one read-only memory (ROM) (e.g., at least one electrically erasable programmable read-only memory (EEPROM)), at least one on-processor memory (e.g., at least one on-processor cache, at least one on-processor buffer, at least one on-processor flash memory, at least one on-processor EEPROM, or a combination thereof), or a combination thereof), at least one storage device (e.g., at least one hard-disk drive, at least one tape drive, at least one solid-state drive, at least one flash drive, at least one readable and/or writable disk of at least one optical drive configured to read from and/or write to the at least one readable and/or writable disk, or a combination thereof), or a combination thereof.

The herein described subject matter sometimes illustrates different components contained within, or connected with, different other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected”, or “operably coupled”, to each other to achieve the desired functionality, and any two components capable of being so associated can also be viewed as being “operably couplable”, to each other to achieve the desired functionality. Specific examples of operably couplable include but are not limited to physically mateable and/or physically interacting components and/or wirelessly interactable and/or wirelessly interacting components and/or logically interacting and/or logically interactable components.

Those having skill in the art will recognize that the state of the art has progressed to the point where there is little distinction left between hardware and software implementations of aspects of systems; the use of hardware or software is generally (but not always, in that in certain contexts the choice between hardware and software can become significant) a design choice representing cost vs. efficiency tradeoffs. Those having skill in the art will appreciate that there are various vehicles by which processes and/or systems and/or other technologies described herein can be implemented (e.g., hardware, software, and/or firmware), and that the preferred vehicle will vary with the context in which the processes and/or systems and/or other technologies are deployed. For example, if an implementer determines that speed and accuracy are paramount, the implementer may opt for a mainly hardware and/or firmware vehicle; alternatively, if flexibility is paramount, the implementer may opt for a mainly software implementation; or, yet again alternatively, the implementer may opt for some combination of hardware, software, and/or firmware. Hence, there are several possible vehicles by which the processes and/or devices and/or other technologies described herein may be implemented, none of which is inherently superior to the other in that any vehicle to be utilized is a choice dependent upon the context in which the vehicle will be deployed and the specific concerns (e.g., speed, flexibility, or predictability) of the implementer, any of which may vary.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

What is claimed is:

1. A heat reuse system, comprising:
a system housing configured to house a rack;
a first power supply configured to be electrically connectable to one or more power shelves of the housed rack; and
a thermoelectric generation system mounted within the system housing such that the housed rack is under the thermoelectric generation system;
wherein the first power supply is configured to draw power from the thermoelectric generation system.

2. The heat reuse system of claim 1, wherein the thermoelectric generation system comprises:
a plurality of thermoelectric generator pads;
a pad mounting component corresponding to each separate thermoelectric generator pad; and
a phase change carrying material;
wherein each thermoelectric generator pad is attached to the phase change carrying material via a corresponding pad mounting component.

3. The heat reuse system of claim 2, wherein the thermoelectric generator pads are in electrical connection in sequence.

4. The heat reuse system of claim 1, wherein the thermoelectric generation system comprises a temperature differential having a cold side and a hot side, the hot side facing the housed rack.

5. The heat reuse system of claim 1, wherein the one or more power shelves are rated to deliver more than 10 kilowatts of power in total.

6. The heat reuse system of claim 1, wherein the one or more power shelves are rated to deliver more than 100 kilowatts of power in total.

7. The heat reuse system of claim 1, wherein the first power supply is configured to be electrically connectable to a busbar and to draw power from the busbar.

8. The heat reuse system of claim 7, wherein the first power supply is configured to swap between drawing power from the thermoelectric generation system and the busbar.

9. The heat reuse system of claim 1, wherein the system housing further comprises a second power supply configured to be electrically connectable to one or more power shelves and to a busbar, and to draw power from the busbar.

10. The heat reuse system of claim 9, wherein the second power supply is rated to deliver more than 10 kilowatts of power.

11. The heat reuse system of claim 9, wherein the second power supply is rated to deliver more than 100 kilowatts of power.
